(19) United States
(12) Patent Application Publication
(10) Pub. No.: US 2005/0099413 A1
(43) Pub. Date: May 12, 2005

(54) Method of resetting a shut down integrated circuit spontaneously and the monitor thereof

(76) Inventors: Chien-Szu Chiu, Lujhu Township (TW); Yi-Hsiang Kao, Lujhu Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/982,117

(22) Filed: Nov. 5, 2004

(30) Foreign Application Priority Data
Nov. 11, 2003 (TW) 92131602

(51) Int. Cl. H03L 7/00; G09G 5/00

(52) U.S. Cl. 345/211

(57) ABSTRACT

A monitor including an integrated circuit with an operating voltage and a control unit for controlling the integrated circuit is provided. The control unit includes a driving unit, a counter, and a resetting unit. The control unit is used for sending out a command to drive the integrated circuit and receiving an acknowledge signal responded by the integrated circuit. The counter is coupled to the driving unit, and the counter value of the counter has an initial vale. The resetting unit is coupled to the counter for resetting the control unit. When the operating voltage is lower than a threshold voltage causing the integrated circuit to be shut down, the driving unit will repeatedly send out the command to drive the integrated circuit. If the driving unit drives the integrated circuit but the integrated circuit does not respond the acknowledge signal, the counter value will be increased by one. When the counter value is larger than the first value, the resetting unit will reset the control unit to restore a normal operation of the integrated circuit.

This application claims the benefit of Taiwan application Serial No. 92131602, filed Nov. 11, 2003, the subject matter of which is incorporated herein by reference.

### BACKGROUND OF THE INVENTION

1. Field of the Invention

The invention relates in general to a method of resetting a shut down integrated circuit (IC) and the monitor thereof, and more particularly to a method of using a control unit to detect and reset a shut down IC and the monitor thereof.

2. Description of the Related Art

Referring to FIG. 1A, a block diagram of a conventional cathode ray tube (CRT) monitor is shown. The CRT monitor 100 includes a MCU 110 and a bias IC 120. The MCU 110 uses an I2C bus 130 to control the bias IC 120, wherein the operating voltage Vs of the bias IC 120 ranges between 8.2V and 10V. Normally, when the MCU 110 is changing an operating mode such as the shifting of a window frame, the power supply will be cut off suddenly and restored spontaneously. Consequently, the operating voltage Vs will be dropped to below 8.2V abruptly, causing the bias IC 120 to be shut down. Meanwhile, the MCU 110 is not reset and does not know that the bias IC 120 has been shut down, resulting in a malfunction of the CRT monitor 100.

Conventionally, an additional detecting device is used to detect the above mentioned sudden voltage change and reset the MCU 110 so as to maintain a normal operation of the entire system. Referring to FIG. 1B, a structural diagram of a microprocessor resetting apparatus disclosed in the American patent of U.S. Pat. No. 4,586,179 is shown. A source voltage level detector (SVLD) 140 and a power up detector 150 are used to detect the change in the operating voltage V1 of the microprocessor 160. When the operating voltage V1 is lower than 4.5V, the power voltage level detector 140 will actuate a resetting trigger 170 to reset the microprocessor 110. According to a watch-dog counter 180, the resetting trigger 170 resets the microprocessor 110 until the operating voltage V1 has arisen to be above 5V, and then the microprocessor 110 restore a normal operation. However, the resetting apparatus must use additional analog/digital circuits such as the power voltage level detector 140 and the power up detector 150 to detect the change in the operating voltage V1 so as to reset the microprocessor 160. Therefore, the system becomes more complicated and the design costs also rise up.

### SUMMARY OF THE INVENTION

It is therefore an object of the invention to provide a method of resetting a shut down integrated circuit spontaneously and the monitor thereof. The control unit of the monitor automatically detects the shutting down of the integrated circuit and resets to restore a normal operation of the integrated circuit.

The invention achieves the above-identified object by providing a monitor including an IC and a control unit. The IC has an operating voltage, and the control unit is provided for controlling the IC. The control unit includes a driving unit, a counter and a resetting unit. The driving unit is used for sending out the command to drive the IC and receive an acknowledge signal corresponding to the command responded by the IC. The counter and the driving unit are coupled together, wherein the counter value of the counter has an initial value. The resetting unit is coupled to the counter for resetting the control unit, wherein the control unit uses an I2C bus to control the IC, and the driving unit sends out the command to program the IC through the I2C bus. When the operating voltage is dropped to below the threshold voltage causing the IC to be shut down, the driving unit will repeatedly send out the command to drive IC. When the driving unit drives the IC but the IC does not respond the acknowledge signal, the counter value is increased by one. If the counter value is larger than the first value, the resetting unit will reset the control unit to restore a normal operation of the IC. By means of a simple circuit design, the control unit can detect and reset a shut down IC to restore a normal operation instantly.

According to the object of the invention, a method of resetting a shut down IC spontaneously is provided. The method is applied in a monitor, including a control unit for controlling the IC. The method is briefly disclosed below. Set the value of the parameter k as an initial value. The control unit sends out the command to drive the IC. If the IC does not respond an acknowledge signal to the control unit, proceed to the next step to determine whether the parameter k is larger than the first value. If the parameter k is not larger than the first value, increase the value of the parameter k and return to the step of driving the IC. Reset the control unit and return to the step of driving the IC. By means of a simple circuit design, the shutting down of the IC can be detected instantly and the IC can restore a normal operation by the control unit reset.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a block diagram of a conventional CRT monitor;

FIG. 1B is a structural diagram of a microprocessor resetting apparatus disclosed in the American patent of U.S. Pat. No. 4,586,179;

FIG. 2 is a block diagram of a CRT monitor according to a preferred embodiment of the invention; and

FIG. 3 is a flowchart of the method of resetting a shut down IC spontaneously according to a preferred embodiment of the invention.

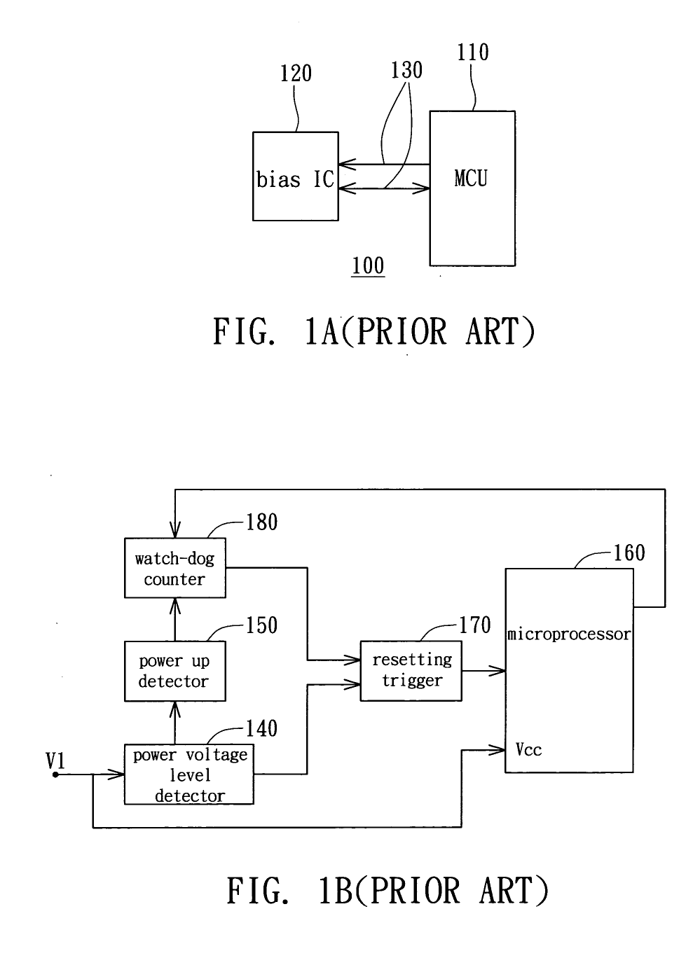

### DETAILED DESCRIPTION OF THE INVENTION

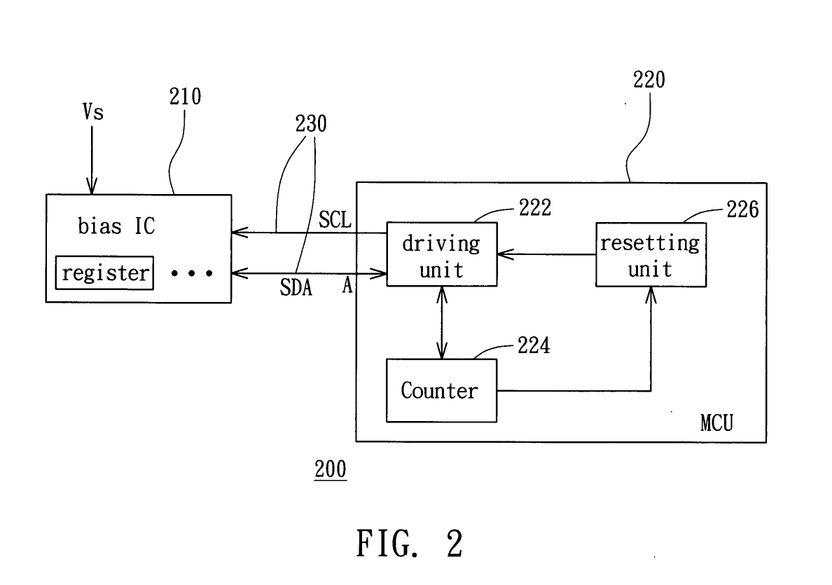

The feature of the invention lies in by using the feature that the IC inside the monitor will respond to the control command of the control unit, when an operating power supply is cut off suddenly and restored spontaneously, the control unit will detect and reset a shutting down IC and restore a normal operation of the IC. In the following, a CRT monitor is taken as an example to describe the method how to reset the shut down IC spontaneously by the control unit (MCU) in the invention.
Referring to FIG. 2, a structural diagram of a CRT monitor according to a preferred embodiment of the invention is shown. The CRT monitor 200 includes a bias IC 210 and a MCU 220. The bias IC 210 has a number of registers 212 for respectively performing the operations of horizontal scanning, vertical scanning, and so forth, wherein the bias IC 210 has an operating voltage Vs normally ranging between 8.2 V and 10 V. When the operating voltage Vs is lower than 8.2V, the bias IC 210 will be shut down. The MCU 220 uses an inter integrated circuit (I2C) bus 230 to control the bias IC 210. The I2C bus 230 normally includes transmission lines SCL and SDA.

The transmission line SCL is used in the one-way clock signal transmission from the MCU 220 to the bias IC 210, while the transmission line SDA is used to transmit the control command from the MCU 220 to the bias IC 210 and the acknowledge signal A responded by the bias IC 210. The MCU 220 includes a driving unit 222, a counter 224 and a resetting unit 226. The driving unit 222 uses the I2C bus 230 to send out the command to program the registers 212 of the bias IC 210 and receive the acknowledge signal A responded by the bias IC 210. The counter 224 and the driving unit 222 are coupled together, and the initial value of the counter value Counter of the counter 224 is 0. When the driving unit 222 sends out the command to program the bias IC 210, and the bias IC 210 does not respond the acknowledge signal A, the counter value Counter is increased by one. Besides, the resetting unit 226 is coupled to the counter 224 for resetting the MCU 220.

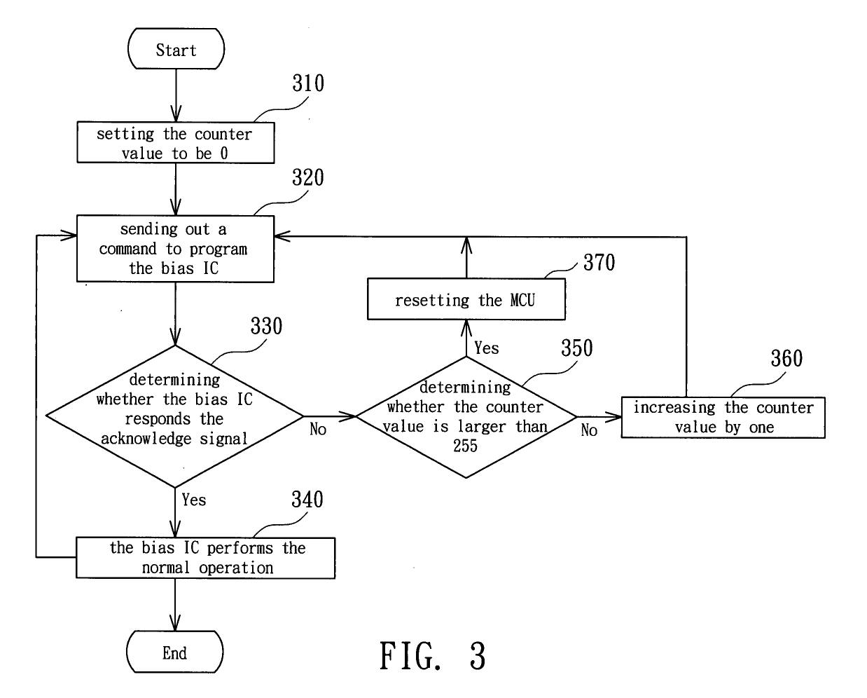

Referring to FIG. 3, a flowchart of the method of resetting a shut down IC spontaneously according to a preferred embodiment of the invention is shown. The steps of the method are disclosed below. First, in the step 310, set the counter value Counter of the counter 224 to be 0. Next, in the step 320, send out a command for programming the bias IC 210, i.e., the driving unit 222 of the MCU 220 sends out a programming command through the I2C bus 230 to program the register 212 of the bias IC 210, a horizontal scanning register for instance. After that, in the step 330, determine whether the bias IC 210 responds the acknowledge signal A to the driving unit 222 of the MCU 220. If the bias IC 210 responds the acknowledge signal A, in the step 340, perform normal operation of horizontal scanning by the bias IC 210, and returns to the step 320, continue to send out the command by the driving unit 222 to program other register 212 of the bias IC 210, a vertical scanning register for instance. If the bias IC 210 does not respond the acknowledge signal A, in to the step 350, determine whether the counter value Counter is larger than 255. If the counter value Counter is not larger than 255, then in the step 360, increase the counter value Counter by one and return to the step 320, where the driving unit 222 repeatedly sends out the command to program the horizontal scanning register 212 of the bias IC 210. If the counter value Counter is larger than 255, which means the bias IC 210 has been shut down, then proceed to the step 370 to reset the MCU 220, meanwhile, the driving unit 222 resets the bias IC 210 so that normal operation of the bias IC 210 is restored, and return to the step 320.

Although the invention is exemplified by using the bias IC 210 of the CRT monitor 200 as an example, however, the method of resetting a shut down IC spontaneously can also be applied to other ICs using an I2C bus, such as an audio IC and a vide IC, in the CRT monitor 200. The method can even be applied to an analog-to-digital converter (ADC) circuit of a liquid crystal displayer (LCD).

According to the preferred embodiment disclosed above, the advantage of the invention lies in the shut down IC can restore a normal operation spontaneously by using the feature that the IC inside the monitor will respond to the control signal of the MCU. When the IC is shut down due to sudden power cut off, the MCU repeatedly sends out the command to program the IC to execute the same functional operation and receive the acknowledge signal responded by the IC. If the MCU sends out the command to program the IC but does not receive any responded acknowledge signal from the IC more than a predetermined number of times, the MCU will be automatically reset so that the shut down IC can restore its normal operation. Therefore, a shut down IC can restore a normal operation spontaneously by means of a simple circuit design without using any additional analog/digital circuit like the prior art does.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A monitor, comprising;
an integrated circuit, having an operating voltage;
a control unit, for controlling the integrated circuit, the control unit comprising;
a driving unit, for sending out a command to drive the integrated circuit and receive an acknowledge signal corresponding to the command responded by the integrated circuit;
a counter, coupled to the driving unit, wherein the counter value of the counter has an initial value; and
a resetting unit, coupled to the counter, for resetting the control unit;
wherein when the operating voltage is lower than a threshold voltage causing the integrated circuit to be shut down, the driving unit will repeatedly send out the command to drive the integrated circuit, and if the driving unit drives the integrated circuit but the integrated circuit does not respond the acknowledge signal, the counter value is increased by one, while when the counter value is larger than a first value, the resetting unit will reset the control unit to restore a normal operation of the integrated circuit.

2. The monitor according to claim 1, wherein the command is for programming the integrated circuit.

3. The monitor according to claim 1, wherein the control unit uses an inter integrated circuit (I2C) bus to control the integrated circuit.

4. The monitor according to claim 3, wherein the monitor is a cathode ray tube (CRT) monitor.

5. The monitor according to claim 4, wherein the integrated circuit is a bias integrated circuit.

6. The monitor according to claim 3, wherein the monitor is a liquid crystal display (LCD).

7. The monitor according to claim 6, wherein the integrated circuit is an analog-to-digital converter.

8. The monitor according to claim 1, wherein when the resetting unit is resetting the control unit, the driving unit resets the integrated circuit and restores the normal operation of the integrated circuit.

9. A method of resetting a shut down integrated circuit spontaneously, applied in a monitor, the monitor having a control unit, for controlling the integrated circuit, the method comprising steps of:
setting the value of a parameter k as an initial value;
sending out a command to drive the integrated circuit by the control unit;
proceeding to the next step if the integrated circuit does not respond an acknowledge signal corresponding to the command to the control unit;
determining whether the value of the parameter k is larger than a first value, increasing the value of parameter k if the value of the parameter k is not larger than the first value, and returning to the step of driving the integrated circuit; and
resetting the control unit to restore a normal operation of the integrated circuit and returning to the step of driving the integrated circuit.

10. The method according to claim 9, wherein the control unit uses an I2C bus to control the integrated circuit.

11. The method according to claim 9, wherein the command is for programming the integrated circuit.

12. The method according to claim 11, wherein the integrated circuit has a plurality of registers, and the control unit programs the registers by sending out the command for programming the integrated circuit.

13. The method according to claim 9, wherein the integrated circuit has an operating voltage, and when the operating voltage is lower than a threshold voltage causing the integrated circuit to be shut down, the control unit will repeatedly send out the command to drive the integrated circuit, thereby detecting whether the integrated circuit has been shut down.

14. The method according to claim 9, wherein when the resetting unit resets the control unit, a driving unit of the control unit resets the integrated circuit to restore a normal operation of the integrated circuit.

15. The method according to claim 9, wherein the value of the parameter k is a counter value of a counter of the control unit.
